(19) United States
(12) Patent Application Publication
(10) Pub. No.: US 2026/0254427 A1
(43) Pub. Date: Aug. 27, 2026

(54) HIGH IMPEDANCE BIASING CIRCUIT

(71) Applicant: STMicroelectronics International N.V., Geneva (CH)

(72) Inventors: Alessio Emanuele Vergani, Milano (IT); Enrico Mammei, Vittuone (MI) (IT); Dario Luigi Romeri, Segrate (IT)

(21) Appl. No.: 19/061,279

(22) Filed: Feb. 24, 2025

(51) Int. Cl. H03F 3/45; G11B 5/60

(52) U.S. Cl. CPC H03F 3/45475; G11B 5/607

(57) ABSTRACT

According to an embodiment, a biasing circuit includes a high impedance bias stage coupled to sensor pads connected to a resistive sensor for detecting fly height in a hard disk drive. The circuit employs dual operational transconductance amplifiers with different bandwidths working in conjunction with switching circuitry to establish and maintain bias conditions. A first operational transconductance amplifier with a higher bandwidth provides fast initial settling, while a second operational transconductance amplifier with a lower bandwidth optimizes continuous operation. The architecture supports multiple operating modes, including differential voltage, differential current, and common mode configurations, through various arrangements of transistors, compensation capacitors, and feedback paths.

### TECHNICAL FIELD

The present disclosure generally relates to electronic devices and, in particular embodiments, to a high-impedance biasing circuit.

### BACKGROUND

Hard disk drives store and retrieve data through magnetic heads that float above rapidly spinning disk surfaces. The spacing between the head and disk surface, known as fly height, can range from 10-20 nanometers during normal operation. A thermal actuation system in the head can reduce this spacing to approximately 1 nanometer by creating controlled mechanical deformation through localized heating. This reduced spacing enhances the magnetic coupling between the head and disk surface, enabling higher recording densities and improved signal quality.

The head assembly can incorporate multiple specialized elements, including read/write transducers, a resistive temperature sensor, and a thermal actuator. The temperature sensor monitors head-to-disk spacing by detecting changes in thermal conductivity as the head approaches the disk surface. As the spacing decreases, heat dissipation through the air gap increases, causing measurable changes in the sensor resistance. However, the sensor resistance can vary with temperature and exhibit manufacturing variations between devices.

Signal processing circuits in the drive's preamplifier condition the small analog signals from the temperature sensor to enable precise spacing control. These circuits apply a bias voltage across the sensor and amplify the resulting signals through multiple gain stages. The biasing circuitry establishes a stable operating point while compensating for resistance variations. Filtering networks separate the relevant spacing information from noise and unwanted frequency components.

The preamplifier's analog front-end faces several key challenges in processing the sensor signals. The variable and temperature-dependent nature of the sensor resistance can complicate maintaining consistent gain and frequency response. DC bias voltages are carefully managed to prevent saturation in the amplifier stages. The circuits can achieve a flat frequency response from DC to hundreds of kilohertz while rejecting noise and interference.

Reliable fly height control depends on accurately processing the temperature sensor signals across all operating conditions. Excessive spacing between the head and disk degrades read/write performance and increases error rates. Insufficient spacing risks catastrophic damage from head-disk contact.

### SUMMARY

Technical advantages are generally achieved by embodiments of this disclosure, which describe a high-impedance biasing circuit.

A first aspect relates to a biasing circuit, comprising a high impedance bias stage coupled to first and second sensor pads, wherein the sensor pads are coupled to a resistive sensor for detecting fly height in a hard disk drive; a first operational transconductance amplifier having a first bandwidth; a second operational transconductance amplifier having a second bandwidth lower than the first bandwidth; a transistor coupled to a first supply voltage, the resistive sensor coupled to the transistor; a compensation capacitor coupled between a control terminal of the transistor and one of the supply voltages; and switching circuitry configured to couple the first operational transconductance amplifier to control a control voltage of the transistor during an initial biasing phase, and couple the second operational transconductance amplifier to control the control voltage during a continuous operation phase.

A second aspect relates to a pre-amplifier for a hard disk drive, the pre-amplifier comprising a fly height sensor circuit including a high impedance bias stage coupled to first and second sensor pads; a first operational transconductance amplifier having a first bandwidth; a second operational transconductance amplifier having a second bandwidth lower than the first bandwidth; a transistor coupled between first and second supply voltages, with a resistive sensor coupled to the transistor; a compensation capacitor coupled between a control terminal of the transistor and one of the supply voltages; and switching circuitry configured to couple the first operational transconductance amplifier to control a control voltage of the transistor during an initial biasing phase, and couple the second operational transconductance amplifier to control the control voltage during a continuous operation phase.

A third aspect relates to a method of biasing a resistive sensor in a hard disk drive, the method comprising receiving a differential reference voltage and a common mode reference voltage at a high impedance bias stage coupled to a first sensor pad and a second sensor pad; controlling control voltages of at least one transistor coupled between supply voltages using a first operational transconductance amplifier having a first bandwidth during an initial biasing phase; providing compensation through capacitors coupled between control terminals of the at least one transistor and the supply voltages; transitioning to a second operational transconductance amplifier having a second bandwidth lower than the first bandwidth for a continuous operation phase; and maintaining bias conditions across the resistive sensor while allowing signal detection.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of a circuit for biasing a resistive sensor (R_{SNS}) and reading the sensing signal (S_{SNS}) across the positive input node (IN_{P}) and the negative input node (IN_{M});

FIG. 2 is a schematic of an embodiment biasing circuit coupled to the resistive sensor (R_{SNS});

FIG. 3 is a schematic of an embodiment biasing circuit coupled to the resistive sensor (R_{SNS});

FIG. 4 is a simplified schematic of an example current digital-to-analog converter (DAC) circuit;

FIG. 5 is a schematic of an embodiment biasing circuit coupled to the resistive sensor (R_{SNS});

FIG. 6 is a schematic of an embodiment biasing circuit coupled to the resistive sensor (R_{SNS});

FIG. 7 is a schematic of an example current DAC circuit;

FIG. 8 is a schematic of an embodiment biasing circuit coupled to the resistive sensor (R_{SNS});

FIG. 9 is a flowchart of an embodiment method for operating a biasing circuit in accordance with the embodiments disclosed herein; and

FIG. 10 is a block diagram of a pre-amplifier that is placed on the disk drive head stack assembly of a hard disk drive.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of hard disk drive fly height sensing and laser power monitoring applications, it should also be appreciated that these inventive aspects may also apply to any application requiring precise biasing and measurement of resistive sensors. In particular, aspects of this disclosure may similarly apply to applications needing accurate voltage or current biasing of resistive loads with high impedance sensing, fast settling time, and low noise performance across a wide bandwidth.

A biasing system for hard disk drive applications provides precise detection of head-disk spacing, thermal asperities, and laser mode hop variations in heat-assisted magnetic recording (HAMR) devices. The system includes a preamplifier circuit that monitors head-disk contact, proximity, and surface irregularities through closed-loop control of resistive sensor biasing conditions.

The architecture implements a high-impedance bias stage that can support multiple operating modes: constant differential voltage, constant differential current, common mode voltage (alone or combined with differential modes), and common mode current. The system can accommodate resistive loads from tens of ohms to tens of kilohms while managing currents from hundreds of microamps to milliamps and voltages from tens to hundreds of millivolts. This flexibility enables operation across differential, common mode, dual single-ended, and combined sensor configurations.

Embodiments of the disclosure employ strategically placed compensation capacitors and dual operational transconductance amplifiers (OTAs) operating in distinct phases. A fast OTA establishes initial bias conditions within several microseconds, followed by a transition to a slower OTA optimized for continuous operation with a bandwidth of several kHz. This approach achieves stable operation with a controlled slew rate and transient response while maintaining a high-power supply rejection ratio (PSRR) and common mode rejection ratio (CMRR).

Working with the OTAs and compensation network, the high impedance bias output stage can enable direct voltage sensing across the resistive sensor without dependency on sensor resistance values or other circuit parameters. In voltage bias modes, the architecture can implement a bandpass transfer function with high-pass filtering at closed-loop bandwidth, while current bias modes can support operation from, for example, DC. The system can recover from rapid sensor variations with response times much shorter than the bias loop time constant while maintaining low noise performance from, for example, kilohertz to hundreds of megahertz frequencies.

In embodiments, the high impedance interface between the bias stage and subsequent gain stages can enable independent optimization of each stage, providing enhanced design flexibility and modularity while maintaining smooth turn-on/off characteristics without voltage or current spikes across the resistive sensor. These and additional details are further discussed below.

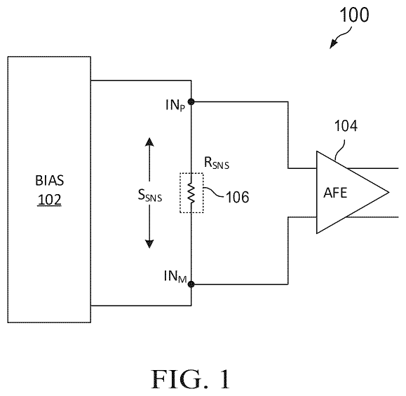

FIG. 1 illustrates a block diagram of a circuit 100 for biasing a resistive sensor (R_{SNS}) 106 and reading the sensing signal (S_{SNS}) across the positive input node (IN_{P}) and the negative input node (IN_{M}). Circuit 100 includes a biasing circuit 102 and an analog front-end (AFE) circuit 104 coupled to the resistive sensor (R_{SNS}) 106, which may (or may not) be arranged as shown. Circuit 100 may include additional components not shown. A detailed description of an example of circuit 100 is provided in U.S. Pat. No. 10,965,254, which is incorporated herein by reference in its entirety.

Maintaining precise spacing between the read/write head and the disk surface in hard disk drive systems impacts drive performance. A heater element in the head assembly can elevate the temperature of a portion of the flying head, causing thermal distortion that reduces the separation between the active read/write elements and the disk surface. This thermal actuation can reduce the normal separation of 10-20 nanometers to approximately 1 nanometer for optimum performance. Operating at larger spacings leads to excessive read and write errors, while insufficient spacing risks catastrophic damage from head-disk contact.

In embodiments, the resistive sensor (R_{SNS}) 106, implemented as a thermal conductivity sensor, monitors this head-disk spacing. When placed on the read/write head assembly, the resistive sensor (R_{SNS}) 106 exhibits resistance variations as the head approaches the disk surface, which acts as a heat sink. These resistance changes generate the sensing signal (S_{SNS}) that indicates the relative spacing between the head and the disk.

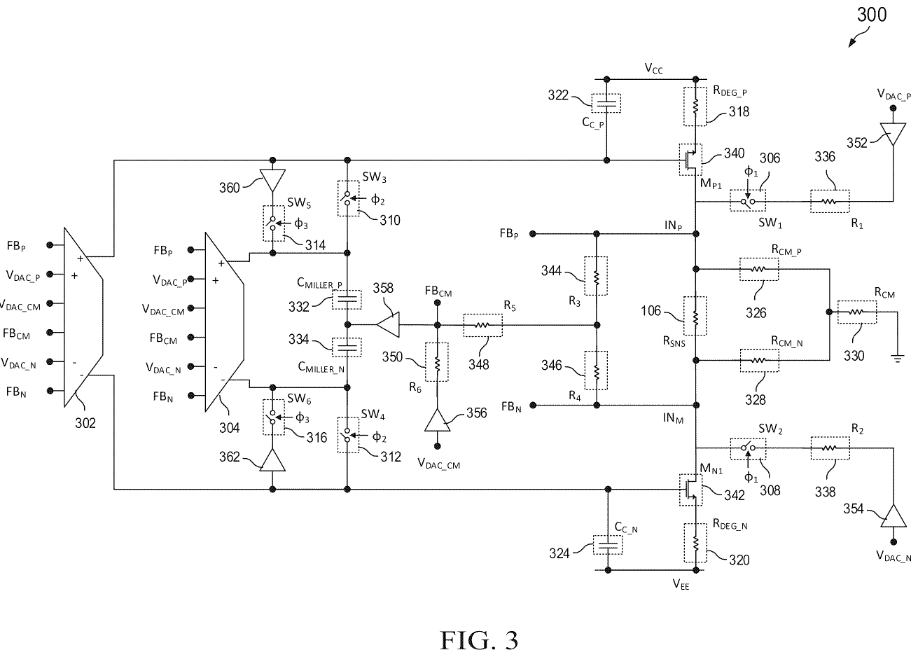

The biasing circuit 102 can operate in multiple modes to bias the resistive sensor (R_{SNS}) 106. In a differential voltage mode, the biasing circuit 102 applies a constant differential voltage across the positive input node (IN_{P}) and the negative input node (IN_{M}). Alternatively, in a differential current mode, the biasing circuit 102 supplies a constant differential current through the resistive sensor (R_{SNS}) 106. The biasing circuit 102 can also apply a common mode voltage, alone or in combination with differential voltage or current biasing. The biasing circuit 102 can also provide a common mode current to the resistive sensor (R_{SNS}) 106 and common mode shunt resistances (e.g. the first shunt resistance (R_{CM_P}) 326, the second shunt resistance (R_{CM_N}) 328, the common-mode resistor (R_{CM}) 330 in FIG. 3). Based on the selected bias mode, the sensing signal (S_{SNS}) manifests as either a sensor voltage or sensing current.

The analog front-end circuit 104 is configured to amplify the sensing signal (S_{SNS}). The output of the analog front-end circuit 104 is coupled to a controller that processes the amplified sensing signal (S_{SNS}) to determine, for example, the fly height of the hard disk drive.

Processing signals from the resistive sensor (R_{SNS}) 106 enables monitoring head-disk contact and proximity. The sensing signal (S_{SNS}) requires filtering and amplification through low-noise analog front-end circuits to extract useful measurements.

Circuit 100 can accommodate a wide range of resistive sensor loads (e.g., from tens of ohms to tens of kilohms), enabling operation across multiple sensor types and operating conditions without requiring circuit redesign. Supporting multiple bit-selectable heads allows the same biasing circuit to be shared across multiple read/write heads in the hard disk drive system, reducing overall system complexity and cost.

In embodiments, once the initial bias conditions are set, the bandwidth adjusts to several kHz for optimal operation. A fast, initial bias settling time in the order of microseconds combined with smooth transitions between operating modes can ensure minimal disruption to drive operations during head switching or operating mode changes.

A high-pass filter response in voltage mode and DC response in current mode can provide flexibility to optimize the measurement bandwidth based on the specific sensing requirements while maintaining low noise performance from, for example, kilohertz to hundreds of megahertz frequencies.

A rapid response time for circuit 100 to sensor variations (e.g., operating faster than the bias loop's time constant) enables accurate tracking of dynamic events like head-disk contact or laser power fluctuations without missing critical data.

Further, high power supply rejection ratio (PSRR) and common-mode rejection ratio (CMRR) across the operating range can eliminate measurement errors induced by, for example, power supply noise or common mode interference. A low-noise performance (e.g., extending from kilohertz to hundreds of megahertz frequencies) can allow circuit 100 to detect slow thermal variations and high-speed contact events while maintaining high measurement accuracy.

Moreover, smooth turn-on and turn-off characteristics can prevent voltage or current spikes across the resistive sensor (R_{SNS}) 106 during power transitions, protecting sensitive components from damage and avoiding false triggering of protection circuits.

Existing solutions proposed to address these challenges resulted in complex differential loops operating in parallel, increasing circuit complexity and interaction between feedback paths. These implementations also required additional stages to cancel unwanted contributions from the output impedance transfer function and variations in the resistive sensor value. In contrast, embodiments of the disclosure provide a high-impedance architecture that simplifies the feedback structure while maintaining precise control across multiple operating modes.

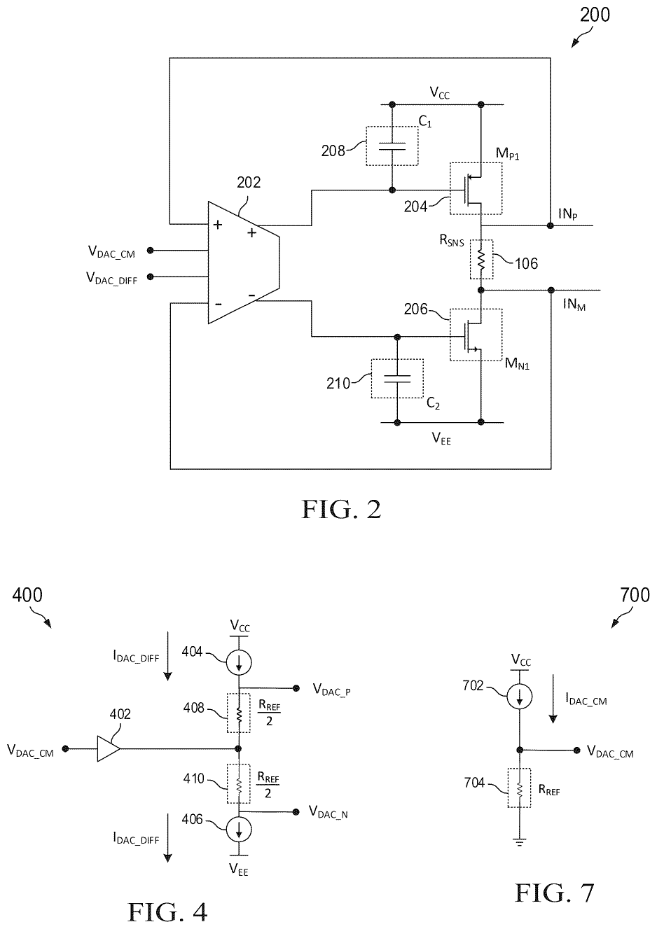

FIG. 2 illustrates a schematic of an embodiment biasing circuit 200 coupled to the resistive sensor (R_{SNS}) 106, which can be implemented as the biasing circuit 102 of FIG. 1. Biasing circuit 200 includes a high-impedance gain stage 202, a p-channel transistor (M_{P}_{₁}) 204, an n-channel transistor (M_{N}_{₁}) 206, the resistive sensor (R_{SNS}) 106, a first capacitor (C₁) 208, and a second capacitor (C₂) 210, which may (or may not) be arranged as shown. Biasing circuit 200 may include additional components not shown.

Depending on the operating mode, biasing circuit 200 establishes precise voltage or current bias conditions across the resistive sensor (R_{SNS}) 106 while maintaining high output impedance. The high-impedance gain stage 202 controls the control voltages of the p-channel transistor (M_{P}_{₁}) 204 and the n-channel transistor (M_{N}_{₁}) 206 to set the desired operating point across the resistive sensor (R_{SNS}) 106 based on the differential voltage reference (V_{DAC_DIFF}) and a common mode voltage reference (V_{DAC_CM}).

The complementary arrangement of the p-channel transistor (M_{P}_{₁}) 204 and the n-channel transistor (M_{N}_{₁}) 206 allows for differential and common mode control of the bias conditions. The high output impedance of the transistors, combined with the first capacitor (C₁) 208 and the second capacitor (C₂) 210, enables accurate sensing of voltage signals across the resistive sensor (R_{SNS}) 106 without loading effects or dependency on the value of the resistive sensor (R_{SNS}) 106.

The p-channel transistor (M_{P}_{₁}) 204 and the n-channel transistor (M_{N}_{₁}) 206 function as voltage-controlled current sources, with the p-channel transistor (M_{P}_{₁}) 204 sourcing current from the first supply voltage (V_{CC}) and the n-channel transistor (M_{N}_{₁}) 206 sinking current to the second supply voltage (VEE). The resistive sensor (R_{SNS}) 106 is coupled between the drain terminals of the p-channel transistor (M_{P}_{₁}) 204 and the n-channel transistor (M_{N}_{₁}) 206.

The first capacitor (C₁) 208 is coupled between the control terminal of the p-channel transistor (M_{P}_{₁}) 204 and the first supply voltage (V_{CC}). The second capacitor (C₂) 210 is coupled between the control terminal of the n-channel transistor (M_{N}_{₁}) 206 and the second supply voltage (VEE).

During normal operation, the first capacitor (C₁) 208 and the second capacitor (C₂) 210 function as compensation elements to improve the power supply rejection ratio (PSRR) by providing low impedance paths to their respective supply rails for high-frequency noise components. This helps isolate the resistive sensor (R_{SNS}) 106 from power supply variations that could otherwise corrupt the sensing signal.

Further, by providing local charge storage, the first capacitor (C₁) 208 and the second capacitor (C₂) 210 can help maintain stable bias voltages at the source terminals of their respective transistors during rapid changes in operating conditions or sensing signals. This can be particularly advantageous when transitioning between different bias modes or responding to fast variations in the resistive sensor (R_{SNS}) 106.

Moreover, the first capacitor (C₁) 208 and the second capacitor (C₂) 210 help filter high-frequency noise generated by the transistors themselves. By providing low impedance paths for these noise components, the capacitors can help maintain a clean bias voltage across the resistive sensor (R_{SNS}) 106, improving the overall noise performance of the sensing system.

The high-impedance gain stage 202 receives a differential voltage reference (V_{DAC_DIFF}) and a common mode voltage reference (V_{DAC_CM}) at its inputs. In embodiments, these reference voltages are generated by digital-to-analog converters (not shown) that convert digital control values into precise analog voltages. The digital control values can be programmed through a register interface, allowing dynamic adjustment of bias conditions based on system requirements or operating modes.

The differential voltage reference (V_{DAC_DIFF}) sets the target voltage difference between the terminals of the resistive sensor (R_{SNS}) 106. In current bias mode, the differential voltage reference (V_{DAC_DIFF}) controls the voltage applied to the high-impedance gain stage 202 to establish the desired current through the resistive sensor (R_{SNS}) 106. The magnitude of the differential voltage reference (V_{DAC_DIFF}) can be adjusted to optimize sensitivity and power consumption for different sensing applications.

The common mode voltage reference (V_{DAC_CM}) sets the average voltage level at which the differential voltage is centered. This common mode voltage ensures that the terminals of the resistive sensor (R_{SNS}) 106 remain within the operating range of subsequent sensing circuits while maintaining proper bias conditions for the p-channel transistor (M_{P}_{₁}) 204 and the n-channel transistor (M_{N}_{₁}) 206. The common mode voltage reference (V_{DAC_CM}) can be adjusted to accommodate different supply voltage ranges or to optimize noise performance.

The high-impedance gain stage 202 implements feedback paths from terminals of the resistive sensor (R_{SNS}) 106 to maintain desired bias conditions. The voltage at the common node between the resistive sensor (R_{SNS}) 106 and the drain terminal of the p-channel transistor (M_{P}_{₁}) 204 is fed back to a positive input of the high-impedance gain stage 202. The voltage at the common node between the resistive sensor (R_{SNS}) 106 and the drain terminal of the n-channel transistor (M_{N}_{₁}) 206 is fed back to a negative input of the high-impedance gain stage 202. The feedback paths create a closed-loop system that regulates differential and common mode voltages across the resistive sensor (R_{SNS}) 106.

For differential voltage biasing, the feedback paths enable the high-impedance gain stage 202 to compare the voltage difference across the resistive sensor (R_{SNS}) 106 with the differential voltage reference (V_{DAC_DIFF}). The high-impedance gain stage 202 adjusts the control voltages of the p-channel transistor (M_{P}_{₁}) 204 and the n-channel transistor (M_{N}_{₁}) 206 to minimize any error between these voltages.

For common mode control, the high-impedance gain stage 202 uses the same feedback signals to compute the average voltage across the resistive sensor (R_{SNS}) 106 and compare it with the common mode voltage reference (V_{DAC_CM}). The high-impedance gain stage 202 adjusts both transistor control voltages symmetrically to maintain the desired common mode level while preserving the differential voltage setting.

This feedback configuration, combined with the high output impedance of the p-channel transistor (M_{P}_{₁}) 204 and the n-channel transistor (M_{N}_{₁}) 206, allows the biasing circuit 200 to maintain precise bias conditions while presenting high impedance to the sensing signal. This enables accurate measurement of resistance variations in the resistive sensor (R_{SNS}) 106 without loading effects that could distort the sensing signal.

The architecture of biasing circuit 200 provides several advantages over conventional approaches. The high output impedance presented by the p-channel transistor (M_{P}_{₁}) 204 and the n-channel transistor (M_{N}_{₁}) 206 to the resistive sensor (R_{SNS}) 106 enables direct voltage sensing without dependency on the sensor resistance value or other circuit parameters. The high-impedance gain stage 202 implements unified bias control through one feedback loop, simplifying the control structure compared to multiple interacting loops. Additionally, the high impedance interface between the biasing circuit 200 and subsequent gain stages allows each stage to be optimized independently, providing greater design flexibility and modularity.

In embodiments, the resistive sensor (R_{SNS}) 106 is coupled to a generic high-impedance gain stage (different from the high-impedance gain stage 202). The feedback configuration illustrated in FIG. 2, combined with the high output impedance of the p-channel transistor (M_{P}_{₁}) 204 and the n-channel transistor (M_{N}_{₁}) 206, allows the biasing circuit 200 to maintain precise bias conditions while presenting high impedance to the sensing signal (S_{SNS}). This enables accurate measurement of resistance variations in the resistive sensor (R_{SNS}) 106 without loading effects that could distort the sensing signal (S_{SNS}).

FIG. 3 illustrates a schematic of an embodiment biasing circuit 300 coupled to the resistive sensor (R_{SNS}) 106, which can be implemented as the biasing circuit 200 of FIG. 2. This implementation shows the configuration for differential voltage biasing with common mode control. The circuit employs dual operational transconductance amplifiers with different gain-bandwidth characteristics, working in conjunction with a network of switches, compensation capacitors, and feedback paths to establish and maintain precise differential voltage and common mode bias conditions.

The differential voltage across the resistive sensor (R_{SNS}) 106 is controlled by the difference between the differential digital-to-analog (DAC) voltages (V_{DAC_P} and V_{DAC_N}). In contrast, the common-mode DAC voltage (V_{DAC_CM}) sets the common mode operating point.

Biasing circuit 300 includes a first operational transconductance amplifier (OTA) 302, a second OTA 304, a first switch (SW₁) 306, a second switch (SW₂) 308, a third switch (SW₃) 310, a fourth switch (SW₄) 312, a fifth switch (SW₅) 314, a sixth switch (SW₆) 316, a first degeneration resistor (R_{DEG_P}) 318, a second degeneration resistor (R_{DEG_N}) 320, a first compensation capacitor (C_{C_P}) 322, a second compensation capacitor (C_{C_N}) 324, a first shunt resistance (R_{CM_P}) 326, a second shunt resistance (R_{CM_N}) 328, a common-mode resistor (R_{CM}) 330, a first Miller capacitor (C_{MILLER_P}) 332, a second Miller capacitor (C_{MILLER_N}) 334, a first resistor (R₁) 336, a second resistor (R₂) 338, a p-channel transistor (M_{P}_{₁}) 340, an n-channel transistor (M_{N}_{₁}) 342, a third resistor (R₃) 344, a fourth resistor (R₄) 346, a fifth resistor (R₅) 348, a sixth resistor (R₆) 350, a first buffer amplifier 352, a second buffer amplifier 354, a third buffer amplifier 356, a fourth buffer amplifier 358, a fifth buffer amplifier 360, and a sixth buffer amplifier 362, which may (or may not) be arranged as shown. Biasing circuit 300 may include additional components not shown. Further, some components shown in FIG. 3 may be optional. For example, the buffer amplifiers in FIG. 3 may be optional.

The first OTA 302 and the second OTA 304 operate in different phases to establish and maintain bias conditions. The first OTA 302 has a lower transconductance to achieve a low gain-bandwidth product (GBWP), preventing interference with signals above kilohertz frequencies. The second OTA 304 has a higher transconductance to achieve a high gain-bandwidth product, enabling fast settling within several microseconds.

Biasing circuit 300 includes multiple feedback paths: a feedback path (FB_{P}) and a feedback path (FB_{N}) for differential feedback, and a common-mode feedback path (FB_{CM}) for common mode control.

Biasing circuit 300 includes a switching network with a three-phase operation: the first switch (SW₁) 306 and the second switch (SW₂) 308 operate with the first phase signal φ₁, the third switch (SW₃) 310 and the fourth switch (SW₄) 312 operate with the second phase signal φ₂, and the fifth switch (SW₅) 314 and the sixth switch (SW₆) 316 operate with the third phase signal φ₃. These phases control the transition between initial biasing and continuous operation modes.

During the first phase (φ₁), the first switch (SW₁) 306, the second switch (S_{W}_{₂}) 308, the third switch (SW₃) 310, and the fourth switch (SW₄) 312 are closed, while the fifth switch (SW₅) 314 and the sixth switch (SW₆) 316 remain open.

In this configuration, the differential DAC voltages (V_{DAC_P} and V_{DAC_N}) are buffered through the first buffer amplifier 352 and the second buffer amplifier 354 and applied directly to the positive input node (IN_{P}) and negative input node (IN_{M}), respectively. The buffered connection provides controlled voltage application while isolating the DAC outputs from the sensor nodes. The first resistor (R₁) 336 and the second resistor (R₂) 338 are arranged in series with an associated buffer amplifier to establish well-defined output impedance during this initialization phase.

This direct biasing path ensures smooth transients at startup by establishing initial operating points at the sensor nodes before activating the main feedback loops. Similarly, during the shutdown, this path maintains controlled voltage conditions at the positive input node (IN_{P}) and negative input node (IN_{M}) while other circuit blocks, such as the operational transconductance amplifiers, current sources, and feedback circuitry, are powering down. This controlled startup and shutdown sequence prevents unwanted voltage spikes across the resistive sensor (R_{SNS}) 106 that could otherwise occur during power transitions.

In the second phase (φ₂), the first switch (S_{W}_{₁}) 306, the second switch (SW₂) 308, the fifth switch (SW₅) 314, and the sixth switch (SW₆) 316 are opened while the third switch (SW₃) 310 and the fourth switch (SW₄) 312 remain closed.

During this phase, the second OTA 304 actively controls the bias voltages set by the differential DAC voltages (V_{DAC_P} and V_{DAC_N}) and the common-mode DAC voltage (V_{DAC_CM}) during fast turn-on transients. The first OTA 302, having lower transconductance, lower operating currents, and reduced bandwidth, remains inactive in the bias control loop during this phase.

The differential feedback path through the second OTA 304 achieves a bandwidth of hundreds of kilohertz. The common mode feedback path can reach bandwidth in the megahertz range, with the actual bandwidth depending on the resistance values of the first shunt resistance (R_{CM_P}) 326, the second shunt resistance (R_{CM_N}) 328, and the common-mode resistor (R_{CM}) 330.

The common mode feedback signal (FB_{CM}) is buffered through the fourth buffer amplifier 358 and applied to the first Miller capacitor (C_{MILLER_P}) 332 and the second Miller capacitor (C_{MILLER_N}) 334. This configuration compensates for the wide variation in common mode impedance seen at the voltage nodes set by the second OTA 304, which can range from hundreds of ohms to hundreds of kilohms depending on the shunt and common mode resistance values.

The third phase (φ₃) begins by opening switches the first switch (SW₁) 306, the second switch (SW₂) 308, the third switch (SW₃) 310, and the fourth switch (SW₄) 312 while closing switches the fifth switch (SW₅) 314 and the sixth switch (SW₆) 316.

In this configuration, the first OTA 302 takes control of the bias voltages, regulating the differential DAC voltages (V_{DAC_P} and V_{DAC_N}) and the common mode voltage reference (V_{DAC_CM}). The lower transconductance of the first OTA 302 optimizes noise performance and enables signal detection from kilohertz frequencies upward during continuous operation.

During this phase, the first Miller capacitor (C_{MILLER_P}) 332 and second Miller capacitor (C_{MILLER_N}) 334 are decoupled from the feedback loop to optimize the power supply rejection ratio (PSRR). Instead, the control voltages of the p-channel transistor (M_{P}_{₁}) 340 and n-channel transistor (M_{N}_{₁}) 342 are buffered through the fifth buffer amplifier 360 and the sixth buffer amplifier 362 and applied to the Miller capacitor terminals.

This buffered connection to the Miller capacitors maintains the proper voltage levels at these nodes, enabling quick and smooth transitions between the third phase (φ₃) and the second phase (φ₂). The arrangement prevents voltage discontinuities that could otherwise disturb the bias conditions across the resistive sensor (R_{SNS}) 106 during phase transitions.

The first resistor (R₁) 336, the second resistor (R₂) 338, the third resistor (R₃) 344, the fourth resistor (R₄) 346, the fifth resistor (R₅) 348, and the sixth resistor (R₆) 350 set various scaling factors and feedback ratios.

In embodiments, the value of the resistive sensor (R_{SNS}) 106 ranges from tens to hundreds of ohms. In embodiments, the value of the first shunt resistance (R_{CM_P}) 326 and the second shunt resistance (R_{CM_N}) 328 range from hundreds of ohms to tens of kilohms. In embodiments, the value of the common-mode resistor (R_{CM}) 330 ranges from zero to hundreds of kilohms. The first degeneration resistor (R_{DEG_P}) 318 and the second degeneration resistor (R_{DEG_N}) 320 are sized large enough to maintain performance at the positive input node (IN_{P}) and negative input node (IN_{M}).

The first compensation capacitor (C_{C_P}) 322 and the second compensation capacitor (C_{C_N}) 324 are designed to filter noise from the first OTA 302 in the signal bandwidth. The first Miller capacitor (C_{MILLER_P}) 332 and the second Miller capacitor (C_{MILLER_N}) 334 work in conjunction with the feedback common mode path (FB_{CM}) to stabilize the common mode loop during the second phase of operation.

The Miller capacitors (i.e., first Miller capacitor (C_{MILLER_P}) 332, second Miller capacitor (C_{MILLER_N}) 334) improve stability by providing frequency-dependent feedback during the second phase (φ₂) of operation. By creating dominant poles in the feedback loops, the Miller capacitors prevent unwanted high-frequency oscillations that could otherwise occur due to the wide range of load impedances presented by the shunt and common mode resistances. The Miller effect multiplies the effective capacitance at the input, allowing relatively small physical capacitors to achieve the necessary compensation.

Power supply rejection ratio optimization varies across operating phases and configurations. During the second phase (φ₂), the Miller capacitors help to stabilize the bias loops avoiding oscillations while maintaining high bandwidth for fast settling. In the third phase (φ₃), direct coupling of compensation capacitors (i.e., the first compensation capacitor (C_{C_P}) 322 and the second compensation capacitor (C_{C_N}) 324) to the supply rails provides optimal PSRR by creating low-impedance paths for the control terminals of the p-channel transistor (M_{P}_{₁}) 340 and the n-channel transistor (M_{N}_{₁}) 342.

Each operating mode requires specific bandwidth characteristics to maintain stability while meeting performance requirements. During initial biasing in the second phase (φ₂), the high-bandwidth OTA (hundreds of kilohertz) enables fast settling within several microseconds. The transition to low-bandwidth operation (e.g., several kHz) in the third phase (φ₃) optimizes noise performance and allows the detection of sensor signals. In voltage bias modes, the high-pass characteristic prevents DC loading effects, while current bias modes maintain DC response for direct current control. The bandwidth requirements balance the competing needs of fast transient response, noise filtering, and accurate signal detection across all operating conditions.

The first buffer amplifier 352, the second buffer amplifier 354, the third buffer amplifier 356, the fourth buffer amplifier 358, the fifth buffer amplifier 360, and the sixth buffer amplifier 362 provide isolation and level shifting where needed.

The first buffer amplifier 352 and the second buffer amplifier 354 isolate the DAC outputs (V_{DAC_P} and V_{DAC_N}) from the sensor nodes during the first phase (φ₁), preventing loading of the DAC outputs while providing controlled voltage application through the first resistor (R₁) 336 and the second resistor (R₂) 338. This buffered interface ensures clean startup transients and protects the DAC circuitry.

The fourth buffer amplifier 358 conditions the common mode feedback signal (FB_{CM}) before it drives the Miller capacitors during the second phase (φ₂). This buffering prevents the loading of the feedback nodes while ensuring proper common mode loop stability across the wide range of impedances present at the sensor nodes. The level shifting capability of the fourth buffer amplifier 358 allows the common mode feedback to operate at the optimal voltage levels for the Miller compensation network.

During the transition between phases, the fifth buffer amplifier 360 and the sixth buffer amplifier 362 buffer the control voltages of the p-channel transistor (M_{P}_{₁}) 340 and the n-channel transistor (M_{N}_{₁}) 342 to the Miller capacitor terminals. This buffered connection maintains proper voltage levels at the capacitor nodes when switching between the second phase (φ₂) and the third phase (φ₃), preventing voltage discontinuities that could disturb the bias conditions.

FIG. 4 illustrates a simplified schematic of an example current digital-to-analog converter (DAC) circuit 400. Current DAC circuit 400 includes a buffer amplifier 402, a first current source 404, a second current source, a first reference resistor 408, and a second reference resistor 410, which may (or may not) be arranged as shown. The current DAC circuit 400 may include additional components that are not shown.

The buffer amplifier 402 receives and buffers the common-mode DAC voltage (V_{DAC_CM}) at its input. The first current source 404 is coupled between the first supply voltage (V_{CC}) and a first node that generates the positive DAC voltage (V_{DAC_P}), while the second current source 406 is coupled between a second node that generates the negative DAC voltage (V_{DAC_N}) and the second supply voltage (V_{EE}). Each current source provides an equal current (I_{DAC_DIFF}).

The first reference resistor 408 is coupled between the first current source 404 and the output of buffer amplifier 402. In contrast, the second reference resistor 410 is coupled between the output of buffer amplifier 402 and the second current source 406. The resistance value of the first reference resistor 408 and the second reference resistor 410 equals

$$\frac{{R}_{REF}}{2} ,$$

where R_{REF} is the total reference resistance.

The buffer amplifier 402 establishes the common mode voltage level at its output. The differential DAC voltages (V_{DAC_P} and V_{DAC_N}) are created by the current (I_{DAC_DIFF}) from the first current source 404 and the second current source 406 multiplied by the first reference resistor 408 and the second reference resistor 410. Since the current sources provide equal currents through matched reference resistors, symmetrical voltage drops are generated above and below the common mode voltage. The magnitude of the differential voltage between the positive DAC voltage (V_{DAC_P}) and the negative DAC voltage (V_{DAC_N}) equals the current (I_{DAC_DIFF}) multiplied by the total reference resistance (R_{REF}).

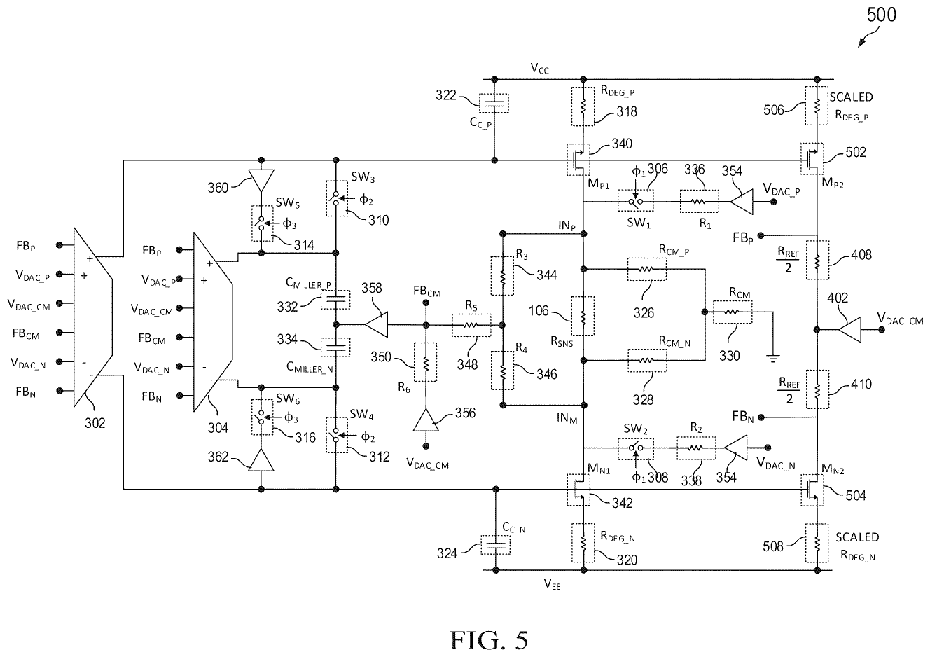

FIG. 5 illustrates a schematic of an embodiment biasing circuit 500 coupled to the resistive sensor (R_{SNS}) 106, which can be implemented as the biasing circuit 200 of FIG. 2. This implementation shows the configuration for differential current biasing with common mode control. The function and structure of circuit components with the same element numbers, which are discussed in FIGS. 3 and 4, are not repeated here for brevity.

In addition to the components previously discussed concerning the biasing circuit 300, the biasing circuit 500 includes the first reference resistor 408, the second reference resistor 410, the buffer amplifier 402, a second p-channel transistor (M_{P}_{₂}) 502, a second n-channel transistor (M_{N}_{₂}) 504, a scaled version of the first degeneration resistor (R_{DEG_P}) 506, and a scaled version of the second degeneration resistor (R_{DEG_N}) 508.

The control terminal of the second p-channel transistor (M_{P}_{₂}) 502 is coupled to the control terminal of the first p-channel transistor (M_{P}_{₁}) 340, while the control terminal of the second n-channel transistor (M_{N}_{₂}) 504 is coupled to the control terminal of the first n-channel transistor (M_{N}_{₁}) 342. This control coupling ensures matched operation between the main and scaled transistor pairs.

Each of the feedback nodes (FB_{P}) and (FB_{N}) is set by the scaled version of the output stage formed by the second p-channel transistor (M_{P}_{₂}) 502 and the second n-channel transistor (M_{N}_{₂}) 504, along with the scaled version of the first degeneration resistor (R_{DEG_P}) 506 and the scaled version of the second degeneration resistor (R_{DEG_N}) 508, respectively. Through the control terminal coupling and matched scaling of the transistors and degeneration resistors, the scaled output stage provides an accurate replica of the currents flowing in the main output stage, enabling precise current control without loading the main bias path.

The differential current flowing between the positive input node (IN_{P}) and negative input node (IN_{M}) is a multiple of the current (I_{DAC_DIFF}), while the common mode voltage on these nodes is set to the common-mode DAC voltage (V_{DAC_CM}) through the buffer amplifier 402. Unlike the voltage bias configuration, this current bias implementation exhibits no high-pass frequency effects on the differential signal at the input nodes.

The common mode feedback loop is closed directly on the positive input node (IN_{P}) and negative input node (IN_{M}), with the buffer amplifier 402 establishing the common mode voltage reference. This configuration maintains the desired common mode operating point while allowing independent control of the differential current through the resistive sensor (R_{SNS}) 106.

The three-phase operation of biasing circuit 500 follows the same switching sequence described for biasing circuit 300. During the first phase (φ₁), the first switch (SW₁) 306, the second switch (SW₂) 308, the third switch (SW₃) 310, and the fourth switch (SW₄) 312 are closed, while the fifth switch (SW₅) 314 and the sixth switch (SW₆) 316 remain open, allowing direct application of the differential DAC voltages (V_{DAC_P} and V_{DAC_N}).

In the second phase (φ₂), the second OTA 304 controls bias conditions with the third switch (SW₃) 310 and the fourth switch (SW₄) 312 closed while all other switches are open, enabling fast settling with Miller compensation active.

The third phase (φ₃) transitions to the first OTA 302 for continuous operation with the fifth switch (SW₅) 314 and the sixth switch (SW₆) 316 closed and all others open, with the Miller capacitors disconnected for optimized PSRR. The difference in biasing circuit 500 is that the feedback signals (FB_{P}) and (FB_{N}) are now derived from the scaled replica output stage rather than directly from the main output stage, enabling precise current mode control while maintaining the same phase sequencing for stable operation.

In embodiments, the scaling relationship between the main transistors (i.e., the first p-channel transistor (M_{P}_{₁}) 340 and the first n-channel transistor (M_{N}_{₁}) 342) and their scaled copies (i.e., the second p-channel transistor (M_{P}_{₂}) 502 and the second n-channel transistor (M_{N}_{₂}) 504) is established through matched geometry ratios and control voltage coupling. The scaled transistors can be designed with proportionally smaller width-to-length ratios than the main transistors (e.g., by a factor of 1 to achieve the best matching or 100 to achieve low power consumption), creating a precise current mirror relationship. This scaling ensures the currents flowing in the scaled copies accurately represent a proportionally smaller version of the main bias currents while minimizing loading effects on the main bias path.

The first reference resistor 408 and the second reference resistor 410 interact with the scaled transistors to establish precise current control. When the differential current (I_{DAC_DIFF}) flows through these matched reference resistors, it creates voltage drops that are applied to the second p-channel transistor (M_{P}_{₂}) 502 and second n-channel transistor (M_{N}_{₂}) 504. Since the scaled transistors share control connections with the first p-channel transistor (M_{P}_{₁}) 340 and first n-channel transistor (M_{N}_{₁}) 342, and their degeneration resistors (i.e., the scaled version of the first degeneration resistor (R_{DEG_P}) 506 and the scaled version of the second degeneration resistor (R_{DEG_N}) 508) are scaled proportionally, the current ratio between the main and scaled paths remains constant. This configuration allows the feedback signals (FB_{P}) and (FB_{N}) to accurately represent the bias conditions without directly loading the main sensor path.

The combination of scaled transistors and reference resistors enables precise current mode operation by translating the reference current (I_{DAC_DIFF}) into proportional currents in both the scaled and main paths. The voltage developed across the total reference resistance (R_{REF}) (i.e., split between the first reference resistor 408 and second reference resistor 410) sets the operating point for the scaled transistors, which then enforce corresponding scaled currents in the main bias path through the matched control voltages.

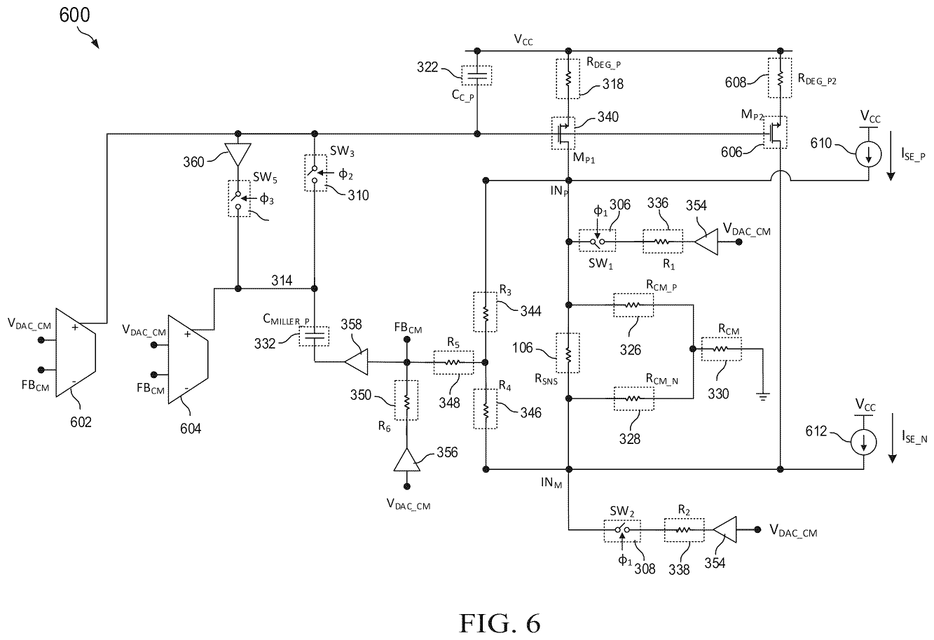

FIG. 6 illustrates a schematic of an embodiment biasing circuit 600 coupled to the resistive sensor (R_{SNS}) 106, which can be implemented as the biasing circuit 200 of FIG. 2. This implementation shows the configuration for common-mode voltage biasing with a differential current control. The function and structure of circuit components with the same element numbers previously discussed are not repeated here for brevity.

The biasing circuit 600 represents a simplified version of the biasing circuit 300 where the negative side of the bias stage is removed. Specifically, the fourth switch (SW₄) 312, the sixth switch (SW₆) 316, the second degeneration resistor (R_{DEG_N}) 320, the second compensation capacitor (C_{C_N}) 324, the n-channel transistor (M_{N}_{₁}) 342, the second Miller capacitor (C_{MILLER_N}) 334, and the sixth buffer amplifier 362 are eliminated. The circuit employs common-mode feedback loops for control.

Further, the first OTA 302 is replaced with the first OTA 602, and the second OTA 304 is replaced with the second OTA 604, where both new OTAs include the common-mode DAC voltage (V_{DAC_CM}) and the common-mode feedback (FB_{CM}) inputs. In embodiments, the first OTA 302 and the second OTA 304 can be used in biasing circuit 600 with their differential parts removed.

Additional components include a second p-channel transistor (M_{P}_{₂}) 606, a second degeneration resistor (R_{DEG_P}_{₂}) 608, a first current source 610, and a second current source 612. The control terminal of the second p-channel transistor (M_{P}_{₂}) 606 is coupled to the control terminal of the first p-channel transistor (M_{P}_{₁}) 340, creating a second copy of the main output stage.

The second degeneration resistor (R_{DEG_P}_{₂}) 608 is coupled between the supply voltage (V_{CC}) and the second p-channel transistor (M_{P}_{₂}) 606, providing source degeneration for the copy similar to how the first degeneration resistor (R_{DEG_P}) 318 functions for the first p-channel transistor (M_{P}_{₁}) 340. This replica of the positive side output stage replaces the now-removed negative side circuitry.

The first current source 610 generates a positive-side current (I_{SE_P}), while the second current source 612 generates a negative-side current (I_{SE_N}). These current sources are optional and can inject currents onto the positive input node (IN_{P}) and negative input node (IN_{M}) to balance or unbalance the common-mode bias. The common-mode voltage loop makes half of this single-ended current differential on the input nodes.

The operation of biasing circuit 600 differs from previous implementations in several ways. The first phase (φ₁) is optional and no longer strictly required for smooth turn-on, making the first switch (SW₁) 306, the second switch (SW₂) 308, the first resistor (R₁) 336, and the second resistor (R₂) 338 optional.

During the second phase (φ₂), the second OTA 604 controls the common-mode bias voltage on the input pads during fast turn-on transients, with the effectiveness of Miller compensation depending on common-mode impedance at the input nodes. Therefore, the first Miller compensation capacitance (C_{MILLER_P}) 332 is optional.

In the third phase (φ₃), the first OTA 602 takes control of the bias voltage on the input nodes for continuous operation.

The removal of the negative side circuitry in biasing circuit 600 is possible because the common-mode voltage biasing configuration requires positive-side and negative-side control to establish the desired operating point. Since the circuit primarily regulates the common-mode voltage level through the first p-channel transistor (M_{P}_{₁}) 340 and the second p-channel transistor (M_{P}_{₂}) 606, the complementary negative-side components, including the first n-channel transistor (M_{N}_{₁}) 342, the second degeneration resistor (R_{DEG_N}) 320, and the second compensation capacitor (C_{C_N}) 324 become redundant. The elimination of these components simplifies the circuit while maintaining full control over the common-mode operating point.

Using only common-mode feedback provides several advantages in this configuration. First, it reduces loop interaction and potential stability issues that could arise from multiple competing feedback paths. The single common-mode feedback path through the common-mode feedback signal (FB_{CM}) provides direct control over the average voltage at the positive input node (IN_{P}) and negative input node (IN_{M}). Second, the simplified feedback structure allows the first OTA 602 and second OTA 604 to be optimized specifically for common-mode control, improving their response to common-mode variations while maintaining high power supply rejection ratio (PSRR).

The common-mode architecture also enables efficient integration with the optional single-ended current sources. The first current source 610 and second current source 612 can inject the positive-side current (I_{SE_P}) and negative-side current (I_{SE_N}), respectively, to create controlled differential currents, while the common-mode feedback loop automatically adjusts to maintain the desired common-mode voltage level.

FIG. 7 illustrates a schematic of an example current DAC circuit 700. Current DAC circuit 700 includes a current source 702 and a reference resistor (R_{REF}) 704, which may (or may not) be arranged as shown. The current DAC circuit 700 may include additional components that are not shown.

The current source 702 is coupled between the supply voltage (V_{CC}) and a node that generates the common-mode DAC voltage (V_{DAC_CM}). The current source 702 provides a common-mode current (I_{DAC_CM}). The reference resistor (R_{REF}) 704 is coupled between the common-mode DAC voltage (V_{DAC_CM}) node and ground.

The common-mode DAC voltage (V_{DAC_CM}) is generated by the common-mode current (I_{DAC_CM}) from current source 702 flowing through the reference resistor (R_{REF}) 704. The magnitude of the common-mode DAC voltage (V_{DAC_CM}) equals I_{DAC_CM} multiplied by R_{REF}. This configuration provides a simple and precise method for generating the common-mode reference voltage used in the biasing circuits previously described.

Unlike the differential DAC configurations, this circuit uses a single current source and reference resistor, as it generates only a common-mode voltage reference rather than differential voltages. The value of R_{REF} can be selected to achieve the desired voltage range based on the available common-mode current (I_{DAC_CM}).

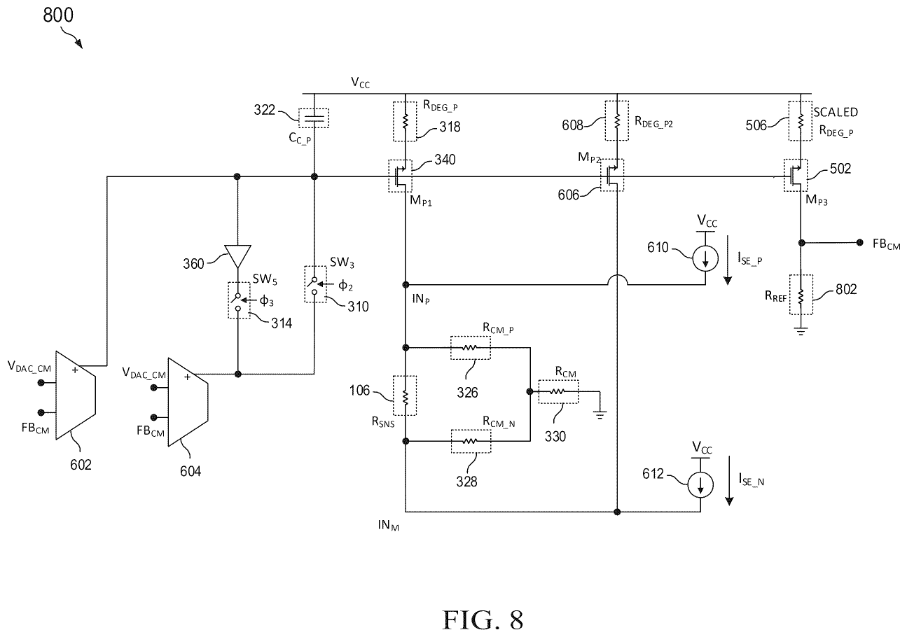

FIG. 8 illustrates a schematic of an embodiment biasing circuit 800 coupled to the resistive sensor (R_{SNS}) 106, which can be implemented as the biasing circuit 200 of FIG. 2. This implementation shows the configuration for common-mode current biasing with a single-ended current control. The function and structure of circuit components with the same element numbers previously discussed are not repeated here for brevity.

The biasing circuit 800 represents a further simplified version where numerous components have been removed (with reference to biasing circuit 300), including the first OTA 302, the second OTA 304, the sixth buffer amplifier 362, the first switch (SW₁) 306, the fourth switch (SW₄) 312, the sixth switch (SW₆) 316, the first Miller capacitor (C_{MILLER_P}) 332, the second Miller capacitor (C_{MILLER_N}) 334, the first resistor (R₁) 336, the third resistor (R₃) 344, the fourth resistor (R₄) 346, the fifth resistor (R₅) 348, the sixth resistor (R₆) 350, the second buffer amplifier 354, the third buffer amplifier 356, the fourth buffer amplifier 358, the n-channel transistor (M_{N}_{₁}) 342, the second degeneration resistor (R_{DEG_N}) 320, and the second compensation capacitor (C_{C_N}) 324.

New components added to the circuit include (with reference to the biasing circuit 300): a third p-channel transistor (M_{P}_{₃}) 502, the scaled version of the degeneration resistor (R_{DEG_P}) 506, the second p-channel transistor (M_{P}_{₂}) 606, the second degeneration resistor (R_{DEG_P}_{₂}) 608, a reference resistor (R_{REF}) 802, the first current source 610, the second current source 612, the first OTA 602, and the second OTA 604, which may (or may not) be arranged as shown. Biasing circuit 800 may include additional components not shown.

The common-mode DAC voltage (V_{DAC_CM}) is generated by the common-mode current (I_{DAC_CM}) from current source 702 flowing through the reference resistor (R_{REF}) 704, as detailed in FIG. 7. The common mode feedback loop is closed on a scaled copy formed by the third p-channel transistor (M_{P}_{₃}) 502 and the scaled version of the degeneration resistor (R_{DEG_P}) 506. This configuration ensures that the common-mode current flowing from the input pads (IN_{P} and IN_{M}) is a multiple of the common-mode current (I_{DAC_CM}).

A characteristic of this configuration is the absence of high-pass frequency effects on the differential and common mode signals at the input nodes (IN_{P} and IN_{M}). The optional current sources 610 and 612 can inject the positive-side current (I_{SE_P}) and negative-side current (I_{SE_N}), respectively, onto the input pads to balance or unbalance the common mode bias as needed.

The biasing circuit 800 operates with a simplified two-phase structure, as the first phase (φ₁) is eliminated in this configuration, although it can be implemented in some embodiments. During the second phase (φ₂), the third switch (SW₃) 310 is closed while the fifth switch (SW₅) 314 remains open. The second OTA 604 controls the common-mode bias voltage on the input pads during fast turn-on transients. In the third phase (_{φ3}), the third switch (SW₃) 310 opens and the fifth switch (SW₅) 314 closes, engaging the first OTA 602 with its lower transconductance for continuous operation. The transitions between phases maintain smooth bias conditions across the resistive sensor (R_{SNS}) 106 while establishing the desired common mode current flow through the scaled output stage.

In embodiments, the second phase (φ₂) operation can incorporate Miller compensation through the first Miller capacitor (C_{MILLER_P}) 332 coupled between the output of the second OTA 604 and the output of a buffer amplifier that replicates the voltage at the common mode feedback node (FB_{CM}). The Miller compensation can provide frequency-dependent feedback that enhances stability during the fast turn-on transients. The effectiveness of the Miller compensation varies based on the common-mode impedance present at the positive input node (IN_{P}) and negative input node (IN_{M}). When implemented, the Miller capacitor can create a dominant pole in the feedback loop, helping prevent unwanted high-frequency oscillations that may occur due to the rapid bias voltage adjustments during this phase. A relatively small physical capacitor can achieve effective compensation through the Miller effect.

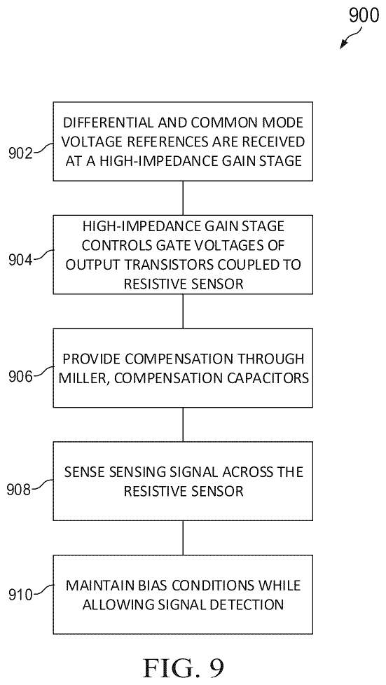

FIG. 9 illustrates a flowchart of an embodiment method 900 for operating a biasing circuit in accordance with the embodiments disclosed herein. It is noted that all steps outlined in the method are not necessarily required and can be optional. Further, changes to the arrangement of the steps, removal of one or more steps and path connections, and addition of steps and path connections are similarly contemplated.

At step 902, differential and common mode voltage references are received at a high-impedance gain stage. For differential voltage biasing with common mode control, this includes receiving the differential DAC voltage (V_{DAC_DIFF}) and the common-mode DAC voltage (V_{DAC_CM}) at the first OTA 302 and the second OTA 304. In differential current biasing with common mode control, the references additionally drive the scaled replica circuit through a scaled second p-channel transistor and a scaled second n-channel transistor. For common mode voltage biasing with differential current control and common mode current biasing with single-ended current control, only the common-mode DAC voltage (V_{DAC_CM}) is received as they operate in common mode configurations.

At step 904, the high-impedance gain stage controls control voltages of output transistors coupled to the resistive sensor (R_{SNS}) 106. In differential voltage biasing, this involves controlling a first p-channel transistor and a first n-channel transistor between a first supply voltage and a second supply voltage. Differential current biasing adds control of the scaled second p-channel transistor and the scaled second n-channel transistor. Common mode voltage and current biasing control only p-channel transistors in their simplified architectures.

At step 906, compensation is provided through capacitors coupled to the supply voltages. This includes the first compensation capacitor (C_{C_P}) 322 and the second compensation capacitor (C_{C_N}) 324 in differential voltage biasing, with additional Miller compensation through the first Miller capacitor (C_{MILLER_P}) 332 and the second Miller capacitor (C_{MILLER_N}) 334 during a second phase of operation. Differential current biasing, common mode voltage biasing, and common mode current biasing implement variations of this compensation scheme based on their specific architectures.

At step 908, voltages across the resistive sensor (R_{SNS}) 106 are sensed through a high-impedance interface. For differential voltage biasing, this occurs at the positive input node (IN_{P}) and the negative input node (IN_{M}). Differential current biasing senses through the scaled replica circuit, while common mode voltage and current biasing sense common mode voltages through their simplified feedback paths.

At step 910, bias conditions are maintained while allowing signal detection. This involves transitioning between operating phases in differential voltage and current biasing, from initial biasing through fast settling to continuous operation. Common mode voltage and current biasing maintain common mode bias while allowing injection of the positive-side current (I_{SE_P}) and the negative-side current (I_{SE_N}) for differential control.

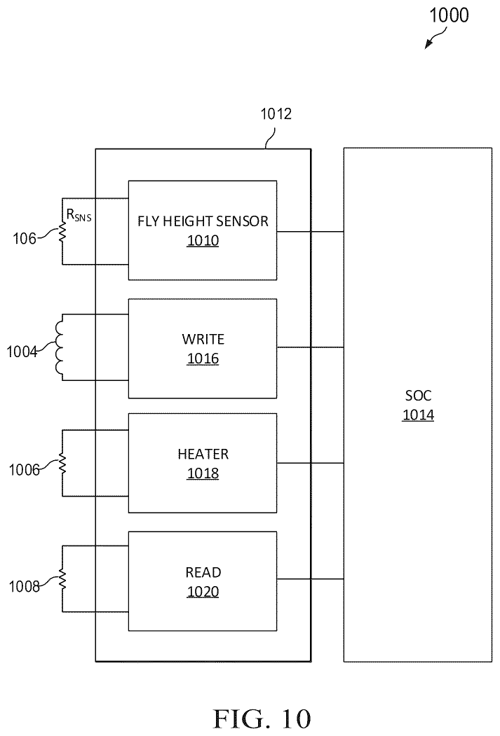

FIG. 10 illustrates a block diagram of a pre-amplifier 1012 that is placed on the disk drive head stack assembly of a hard disk drive. In embodiments, the biasing circuits disclosed herein are implemented within the pre-amplifier 1012.

The disk drive head stack assembly slides over the disk. The pre-amplifier 1012 includes a fly height sensor 1010. In embodiments, the fly height sensor 1010 includes a biasing circuit and an amplifier (not shown). The fly height sensor 1010 is coupled to the resistive sensor (R_{SNS}) 106. The resistive sensor (R_{SNS}) 106 monitors the fly height between the disk drive head and the disk itself.

A write coil 1004 is coupled to the write circuit 1016 (for writing to the disk), a heater resistor 1006 is coupled to the heater circuit 1018 (for controlling the fly height spacing), and a read resistor 1008 is coupled to the read circuit 1020 (for reading from the disk). The fly height sensor 1010, write circuit 1016, heater circuit 1018, and read circuit 1020 are coupled to a system-on-chip (SoC) 1014 for processing.

A first aspect relates to a biasing circuit, comprising a high impedance bias stage coupled to first and second sensor pads, wherein the sensor pads are coupled to a resistive sensor for detecting fly height in a hard disk drive; a first operational transconductance amplifier having a first bandwidth; a second operational transconductance amplifier having a second bandwidth lower than the first bandwidth; a transistor coupled between a first supply voltage and a second supply voltage, the resistive sensor coupled to the transistor; a compensation capacitor coupled between a control terminal of the transistor and one of the supply voltages; and switching circuitry configured to couple the first operational transconductance amplifier to control a control voltage of the transistor during an initial biasing phase, and couple the second operational transconductance amplifier to control the control voltage during a continuous operation phase.

In a first implementation form of the biasing circuit, according to the first aspect as such, the transistor is a p-channel transistor coupled to the first supply voltage, the biasing circuit further comprising an n-channel transistor coupled in series with the p-channel transistor and the second supply voltage, the n-channel transistor arranged between the first supply voltage and the second supply voltage, wherein the resistive sensor is coupled between source terminals of the p-channel transistor and the n-channel transistor, and wherein a second compensation capacitor is coupled between a control terminal of the n-channel transistor and the second supply voltage.

In a second implementation form of the biasing circuit, according to the first aspect as such or any preceding implementation form of the first aspect, the biasing circuit further comprises a current digital-to-analog converter providing a reference current; a first reference resistor and a second reference resistor coupled in series to receive the reference current; a second scaled transistor having a control terminal coupled to the control terminal of the p-channel transistor; and a third scaled transistor having a control terminal coupled to the control terminal of the n-channel transistor, wherein the first reference resistor and the second reference resistor are coupled between the second scaled transistor and the third scaled transistor.

In a third implementation form of the biasing circuit, according to the first aspect as such or any preceding implementation form of the first aspect, the biasing circuit further comprises a scaled transistor having a control terminal coupled to the control terminal of the transistor; a scaled degeneration resistor coupled between the scaled transistor and one of the supply voltages; and a reference resistor coupled to the scaled transistor, wherein feedback for controlling the control voltage originates from a node between the scaled transistor and the reference resistor.

In a fourth implementation form of the biasing circuit, according to the first aspect as such or any preceding implementation form of the first aspect, the biasing circuit further comprises a voltage digital-to-analog converter providing a differential reference voltage and a common mode reference voltage to the first operational transconductance amplifier and the second operational transconductance amplifier; a Miller capacitor, wherein the switching circuitry is configured to couple the Miller capacitor between an output of the first operational transconductance amplifier and the control voltage during the initial biasing phase; and a buffer amplifier coupled between the Miller capacitor and the control voltage during the continuous operation phase.

In a fifth implementation form of the biasing circuit, according to the first aspect as such or any preceding implementation form of the first aspect, the biasing circuit further comprises a first current source coupled to the first sensor pad for injecting a first current; a second current source coupled to the second sensor pad for injecting a second current; and a common mode feedback path coupled between the sensor pads and the first operational transconductance amplifier and the second operational transconductance amplifier, wherein the first current source and the second current source are configured to inject unequal currents to create a controlled differential current while maintaining a common mode voltage level.

In a sixth implementation form of the biasing circuit, according to the first aspect as such or any preceding implementation form of the first aspect, the switching circuitry includes a first switch and a second switch configured to couple reference voltages directly to the sensor pads during a startup phase; a third switch and a fourth switch configured to couple the first operational transconductance amplifier to control the control voltage during the initial biasing phase; and a fifth switch and a sixth switch configured to couple the second operational transconductance amplifier to control the control voltage during the continuous operation phase.

A second aspect relates to a pre-amplifier for a hard disk drive, the pre-amplifier comprising a fly height sensor circuit including a high impedance bias stage coupled to first and second sensor pads; a first operational transconductance amplifier having a first bandwidth; a second operational transconductance amplifier having a second bandwidth lower than the first bandwidth; a transistor coupled between first and second supply voltages, with a resistive sensor coupled to the transistor; a compensation capacitor coupled between a control terminal of the transistor and one of the supply voltages; and switching circuitry configured to couple the first operational transconductance amplifier to control a control voltage of the transistor during an initial biasing phase, and couple the second operational transconductance amplifier to control the control voltage during a continuous operation phase.

In a first implementation form of the pre-amplifier, according to the second aspect as such, the transistor is a p-channel transistor coupled to the first supply voltage; the pre-amplifier further includes an n-channel transistor coupled between the p-channel transistor and the second supply voltage; and during the initial biasing phase, the first operational transconductance amplifier controls control voltages of the p-channel transistor and the n-channel transistor.

In a second implementation form of the pre-amplifier, according to the second aspect as such or any preceding implementation form of the second aspect, during the continuous operation phase the second operational transconductance amplifier maintains the differential and common mode bias conditions with a kilohertz bandwidth; the compensation capacitor provides power supply noise rejection; and the switching circuitry is configured to decouple Miller capacitors from feedback paths to optimize power supply rejection ratio.

In a third implementation form of the pre-amplifier, according to the second aspect as such or any preceding implementation form of the second aspect, the fly height sensor circuit further includes scaled copies of the transistor coupled to reference resistors, wherein during the initial biasing phase, the first operational transconductance amplifier is configured to control current through the scaled copies to establish a differential current through the resistive sensor, and wherein during the continuous operation phase, the second operational transconductance amplifier is configured to maintain the differential current while allowing DC to high frequency signal detection.

In a fourth implementation form of the pre-amplifier, according to the second aspect as such or any preceding implementation form of the second aspect, the fly height sensor circuit further includes a first current source coupled to the first sensor pad; and a second current source coupled to the second sensor pad, wherein during the continuous operation phase the second operational transconductance amplifier is configured to maintain a common mode voltage, and the first current source and the second current source are configured to inject unequal currents to create controlled differential currents.

In a fifth implementation form of the pre-amplifier, according to the second aspect as such or any preceding implementation form of the second aspect, the switching circuitry includes a first switch and a second switch configured to couple reference voltages to the sensor pads during a startup phase before the initial biasing phase; a third switch and a fourth switch configured to engage the first operational transconductance amplifier during the initial biasing phase; and a fifth switch and a sixth switch configured to engage the second operational transconductance amplifier during the continuous operation phase.

In a sixth implementation form of the pre-amplifier, according to the second aspect as such or any preceding implementation form of the second aspect, the first operational transconductance amplifier has higher transconductance than the second operational transconductance amplifier.

A third aspect relates to a method of biasing a resistive sensor in a hard disk drive, the method comprising receiving a differential reference voltage and a common mode reference voltage at a high impedance bias stage coupled to a first sensor pad and a second sensor pad; controlling control voltages of at least one transistor coupled between supply voltages using a first operational transconductance amplifier having a first bandwidth during an initial biasing phase; providing compensation through capacitors coupled between control terminals of the at least one transistor and the supply voltages; transitioning to a second operational transconductance amplifier having a second bandwidth lower than the first bandwidth for a continuous operation phase; and maintaining bias conditions across the resistive sensor while allowing signal detection.

In a first implementation form of the method, according to the third aspect as such, controlling control voltages includes controlling a p-channel transistor coupled to a first supply voltage and an n-channel transistor coupled to a second supply voltage; establishing differential and common mode bias conditions across the resistive sensor coupled between source terminals of the transistors; and achieving settled bias conditions within twenty microseconds.

In a second implementation form of the method, according to the third aspect as such or any preceding implementation form of the third aspect, the method further comprises generating reference currents using a current digital-to-analog converter; applying the reference currents to scaled copies of the at least one transistor; and controlling bias conditions using feedback from the scaled copies.

In a third implementation form of the method, according to the third aspect as such or any preceding implementation form of the third aspect, the method further comprises coupling Miller capacitors between outputs of the first operational transconductance amplifier and the control voltages during the initial biasing phase; decoupling the Miller capacitors during the continuous operation phase; and buffering the control voltages to maintain stable transitions between phases.

In a fourth implementation form of the method, according to the third aspect as such or any preceding implementation form of the third aspect, the method further comprises injecting unequal currents at the first sensor pad and the second sensor pad; maintaining common mode voltage levels through feedback while allowing differential currents; and enabling signal detection from DC to high frequencies.

In a fifth implementation form of the method, according to the third aspect as such or any preceding implementation form of the third aspect, transitioning between phases includes coupling reference voltages directly to the sensor pads during a startup phase; engaging the first operational transconductance amplifier with higher transconductance for fast settling; and switching to the second operational transconductance amplifier with lower transconductance for optimized noise performance.

A fourth aspect relates to a biasing circuit for a resistive sensor, comprising a bias stage coupled to first and second sensor pads; a voltage digital-to-analog converter providing differential and common mode reference voltages; a first operational transconductance amplifier having a first bandwidth; a second OTA having a second bandwidth lower than the first bandwidth; a first set of switches configured to couple the voltage digital-to-analog converter to the sensor pads during a startup phase; a second set of switches configured to couple the first operational transconductance amplifier to control bias voltages on the sensor pads during an initial biasing phase; and a third set of switches configured to couple the second operational transconductance amplifier to control the bias voltages during a continuous biasing phase, wherein the bias stage includes compensation capacitors coupled between the sensor pads and power supply nodes.

A fifth aspect relates to a biasing circuit for a resistive sensor, comprising a bias stage coupled to first and second sensor pads; a current digital-to-analog converter providing a differential reference current; first and second reference resistors coupled to receive the differential reference current; a first operational transconductance amplifier having a first bandwidth; scaled copies of the bias stage components coupled to the reference resistors; a first operational transconductance amplifier having a first bandwidth; a second operational transconductance amplifier having a second bandwidth lower than the first bandwidth; and switching circuitry configured to selectively couple the first operational transconductance amplifier or the second operational transconductance amplifier to control bias voltages on the sensor pads, wherein feedback for controlling the bias voltages is taken from the scaled copies.

A sixth aspect relates to a biasing circuit for a resistive sensor, comprising a bias stage coupled to first and second sensor pads; a current digital-to-analog converter providing a differential reference current; first and second reference resistors coupled to receive the differential reference current; a first operational transconductance amplifier having a first bandwidth; scaled copies of the bias stage components coupled to the reference resistors; a first operational transconductance amplifier having a first bandwidth; a second operational transconductance amplifier having a second bandwidth lower than the first bandwidth; and switching circuitry configured to selectively couple the first operational transconductance amplifier or the second operational transconductance amplifier to control bias voltages on the sensor pads, wherein feedback for controlling the bias voltages is taken from the scaled copies.

A seventh aspect relates to a biasing circuit for a resistive sensor, comprising a bias stage coupled to first and second sensor pads; a current digital-to-analog converter providing a differential reference current; first and second reference resistors coupled to receive the differential reference current; a first operational transconductance amplifier having a first bandwidth; scaled copies of the bias stage components coupled to the reference resistors; a first operational transconductance amplifier having a first bandwidth; a second operational transconductance amplifier having a second bandwidth lower than the first bandwidth; and switching circuitry configured to selectively couple the first operational transconductance amplifier or the second operational transconductance amplifier to control bias voltages on the sensor pads, wherein feedback for controlling the bias voltages is taken from the scaled copies.

An eighth aspect relates to a biasing circuit for a resistive sensor, comprising a high impedance bias stage coupled to first and second sensor pads; a reference voltage or current source; a first operational transconductance amplifier having a first bandwidth; a second first operational transconductance amplifier having a second bandwidth lower than the first bandwidth; switching circuitry configured to couple the reference source directly to the sensor pads during a startup phase, couple the first operational transconductance amplifier to control bias conditions on the sensor pads during an initial biasing phase, and couple the second first operational transconductance amplifier to control the bias conditions during a continuous biasing phase; and compensation capacitors coupled between the power supply nodes and transistor control terminals.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A biasing circuit, comprising:
a high impedance bias stage coupled to first and second sensor pads, wherein the sensor pads are coupled to a resistive sensor for detecting fly height in a hard disk drive;
a first operational transconductance amplifier having a first bandwidth;
a second operational transconductance amplifier having a second bandwidth lower than the first bandwidth;
a transistor coupled to a first supply voltage and the resistive sensor;
a compensation capacitor coupled between a control terminal of the transistor and the first supply voltage; and
switching circuitry configured to:
couple the first operational transconductance amplifier to control a control voltage of the transistor during an initial biasing phase, and
couple the second operational transconductance amplifier to control the control voltage during a continuous operation phase.

2. The biasing circuit of claim 1, wherein the transistor is a p-channel transistor, the biasing circuit further comprising an n-channel transistor coupled in series with the p-channel transistor and a second supply voltage,
wherein the resistive sensor is coupled between source terminals of the p-channel transistor and the n-channel transistor, and
wherein a second compensation capacitor is coupled between a control terminal of the n-channel transistor and the second supply voltage.

3. The biasing circuit of claim 2, further comprising:
a current digital-to-analog converter providing a reference current;
a first reference resistor and a second reference resistor coupled in series to receive the reference current;
a second scaled transistor having a control terminal coupled to the control terminal of the p-channel transistor; and
a third scaled transistor having a control terminal coupled to the control terminal of the n-channel transistor, wherein the first reference resistor and the second reference resistor are coupled between the second scaled transistor and the third scaled transistor.

4. The biasing circuit of claim 1, further comprising:
a scaled transistor having a control terminal coupled to the control terminal of the transistor;
a scaled degeneration resistor coupled between the scaled transistor and the first supply voltage; and
a reference resistor coupled to the scaled transistor, wherein feedback for controlling the control voltage originates from a node between the scaled transistor and the reference resistor.

5. The biasing circuit of claim 1, further comprising:
a voltage digital-to-analog converter providing a differential reference voltage and a common mode reference voltage to the first operational transconductance amplifier and the second operational transconductance amplifier;
a Miller capacitor, wherein the switching circuitry is configured to couple the Miller capacitor between an output of the first operational transconductance amplifier and the control voltage during the initial biasing phase; and
a buffer amplifier coupled between the Miller capacitor and the control voltage during the continuous operation phase.

6. The biasing circuit of claim 1, further comprising:
a first current source coupled to the first sensor pad for injecting a first current;
a second current source coupled to the second sensor pad for injecting a second current; and
a common mode feedback path coupled between the sensor pads and the first operational transconductance amplifier and the second operational transconductance amplifier, wherein the first current source and the second current source are configured to inject unequal currents to create a controlled differential current while maintaining a common mode voltage level.

7. The biasing circuit of claim 1, wherein the switching circuitry includes:
a first switch and a second switch configured to couple reference voltages directly to the sensor pads during a startup phase;
a third switch and a fourth switch configured to couple the first operational transconductance amplifier to control the control voltage during the initial biasing phase; and
a fifth switch and a sixth switch configured to couple the second operational transconductance amplifier to control the control voltage during the continuous operation phase.

8. A pre-amplifier for a hard disk drive, the pre-amplifier comprising a biasing circuit including:
a high impedance bias stage coupled to first and second sensor pads;
a first operational transconductance amplifier having a first bandwidth;
a second operational transconductance amplifier having a second bandwidth lower than the first bandwidth;
a transistor coupled to a first supply voltage and the resistive sensor;
a compensation capacitor coupled between a control terminal of the transistor and the first supply voltage; and
switching circuitry configured to:
couple the first operational transconductance amplifier to control a control voltage of the transistor during an initial biasing phase, and
couple the second operational transconductance amplifier to control the control voltage during a continuous operation phase.

9. The pre-amplifier of claim 8, wherein the transistor is a p-channel transistor, the biasing circuit further comprising an n-channel transistor coupled in series with the p-channel transistor and a second supply voltage,
wherein the resistive sensor is coupled between source terminals of the p-channel transistor and the n-channel transistor, and
wherein a second compensation capacitor is coupled between a control terminal of the n-channel transistor and the second supply voltage.

10. The pre-amplifier of claim 9, wherein during the continuous operation phase:
the second operational transconductance amplifier maintains the differential and common mode bias conditions with a kilohertz bandwidth;
the compensation capacitor provides power supply noise rejection; and
the switching circuitry is configured to decouple Miller capacitors from feedback paths to optimize power supply rejection ratio.

11. The pre-amplifier of claim 8, wherein the biasing circuit further includes:
scaled copies of the transistor coupled to reference resistors,
wherein during the initial biasing phase, the first operational transconductance amplifier is configured to control current through the scaled copies of the transistor to establish a differential current through the resistive sensor, and
wherein during the continuous operation phase, the second operational transconductance amplifier is configured to maintain the differential current while allowing DC to high frequency signal detection.

12. The pre-amplifier of claim 8, wherein the biasing circuit further includes:
a first current source coupled to the first sensor pad; and
a second current source coupled to the second sensor pad,
wherein during the continuous operation phase:
the second operational transconductance amplifier is configured to maintain a common mode voltage, and
the first current source and the second current source are configured to inject unequal currents to create controlled differential currents.

13. The pre-amplifier of claim 8, wherein the switching circuitry includes:
a first switch and a second switch configured to couple reference voltages to the sensor pads during a startup phase before the initial biasing phase;
a third switch and a fourth switch configured to engage the first operational transconductance amplifier during the initial biasing phase; and
a fifth switch and a sixth switch configured to engage the second operational transconductance amplifier during the continuous operation phase.

14. The pre-amplifier of claim 13, wherein the first operational transconductance amplifier has higher transconductance than the second operational transconductance amplifier.

15. A method of biasing a resistive sensor in a hard disk drive, the method comprising:
receiving a differential reference voltage and a common mode reference voltage at a high impedance bias stage coupled to a first sensor pad and a second sensor pad;
controlling control voltages of at least one transistor coupled to supply voltages using a first operational transconductance amplifier having a first bandwidth during an initial biasing phase;
providing compensation through capacitors coupled between control terminals of the at least one transistor and the supply voltages;
transitioning to a second operational transconductance amplifier having a second bandwidth lower than the first bandwidth for a continuous operation phase; and
maintaining bias conditions across the resistive sensor while allowing signal detection.

16. The method of claim 15, wherein controlling control voltages includes:
controlling a p-channel transistor coupled to a first supply voltage and an n-channel transistor coupled to a second supply voltage;
establishing differential and common mode bias conditions across the resistive sensor coupled between source terminals of the transistors; and
achieving settled bias conditions within twenty microseconds.

17. The method of claim 15, further comprising:
generating reference currents using a current digital-to-analog converter;
applying the reference currents to scaled copies of the at least one transistor; and
controlling bias conditions using feedback from the scaled copies of the at least one transistor.

18. The method of claim 15, further comprising:
coupling Miller capacitors between outputs of the first operational transconductance amplifier and the control voltages during the initial biasing phase;
decoupling the Miller capacitors during the continuous operation phase; and
buffering the control voltages to maintain stable transitions between phases.

19. The method of claim 15, further comprising:
injecting unequal currents at the first sensor pad and the second sensor pad;
maintaining common mode voltage levels through feedback while allowing differential currents; and
enabling signal detection from DC to high frequencies.

20. The method of claim 15, wherein transitioning between phases includes:
coupling reference voltages directly to the sensor pads during a startup phase;
engaging the first operational transconductance amplifier with higher transconductance for fast settling; and
switching to the second operational transconductance amplifier with lower transconductance for optimized noise performance.
